(19) United States
(12) Patent Application Publication
(10) Pub. No.: US 2025/0089153 A1
(43) Pub. Date: Mar. 13, 2025

(54) SOLID STATE TRANSFORMER AND STACK-UP STRUCTURE OF PRINTED CIRCUIT BOARD THEREOF

(71) Applicant: DELTA ELECTRONICS, INC., Taoyuan City (TW)

(72) Inventors: Jui-Chien HUNG, Taoyuan City (TW); Wen-Lung HUANG, Taoyuan City (TW); Sheng-Hua LI, Taoyuan City (TW)

(21) Appl. No.: 18/792,346

(22) Filed: Aug. 1, 2024

Related U.S. Application Data
(60) Provisional application No. 63/537,652, filed on Sep. 11, 2023.

(30) Foreign Application Priority Data
Mar. 20, 2024 (CN) 202420548219.4

(51) Int. Cl. H05K 1/02; H05K 1/18; H05K 7/20

(52) U.S. Cl. CPC H05K 1/0204; H05K 1/0209; H05K 1/181; H05K 7/205; H05K 2201/041; H05K 2201/066

(57) ABSTRACT

This disclosure is directed to a solid state transformer and a printed circuit board stack-up structure, the printed circuit board stack-up structure has a plate, a power device, a thermally conductive insulating layer, a heat diffusion layer and a thermal conductor. The plate has a first surface and a second surface respectively disposed at two sides. The power device is arranged on the first surface. The thermally conductive insulating layer is pressed to combine with the second surface and cover the second surface. The heat diffusion layer is pressed to combine with the thermally conductive insulating layer and cover the thermally conductive insulating layer. The thermal conductor is embedded in the plate and respectively connected to the power device and the thermally conductive insulating layer.

### CROSS-REFERENCE TO RELATED APPLICATION

This patent application claims the benefit of U.S. provisional patent application No. 63/537,652 filed on Sep. 11, 2023, which is incorporated by reference herein.

### BACKGROUND OF THE INVENTION

### Technical Field

This disclosure is directed to a stack-up structure of a printed circuit board, in particular to a stack-up structure of a printed circuit board having a thermally conductive insulating layer therein.

### Description of Related Art

A relater-art high-power power device used on a motherboard of an electronic device generate a large amount of heat in an operation. Therefore, the motherboard is generally provided with a heat dissipation device dissipating heat from the power device. The heat dissipation device is usually made of metal conductors, an insulating layer should be provided between the heat dissipation device and the motherboard to avoid short circuits. In an assembly process of the heat dissipation device, both sides of the insulating layer for attaching the motherboard and the heat dissipation device are applied with thermal paste respectively. This assembly process requires two times of the application of thermal paste, so that the manufacturing process is time-consuming. Moreover, when assembling the heat dissipation device to the circuit board, the insulative material tends to be damaged by human operation errors, and a predetermined insulation effect cannot be performed.

In views of this, in order to solve the above disadvantage, the inventor studied related technology and provided a reasonable and effective solution in this disclosure.

### SUMMARY OF THE INVENTION

This disclosure id directed to a stack-up structure of a printed circuit board having a thermally conductive insulating layer therein.

This disclosure is directed to a stack-up structure of a printed circuit board having a plate, a power device, a thermally conductive insulating layer, a heat diffusion layer and a thermal conductor. The plate has a first surface and a second surface opposite to each other. The power device is arranged on the first surface. The thermally conductive insulating layer covers the second surface and is pressed to combine with the second surface. The heat diffusion layer covers the thermally conductive insulating layer and is pressed to combine with the thermally conductive insulating layer. The thermal conductor is embedded in the plate and connected with the power device and the thermally conductive insulating layer, respectively.

According to an embodiment of this disclosure, the stack-up structure of the printed circuit board further has a heat dissipation device, the heat dissipation device assembled on the plate and the heat diffusion layer disposed between the heat dissipation device and the thermally conductive insulating layer.

According to an embodiment of this disclosure, the stack-up structure of the printed circuit board further has a thermally conductive layer, the thermally conductive layer is disposed between the heat dissipation device and the heat diffusion layer.

According to an embodiment of this disclosure, the heat dissipation device is electrically connected with the heat diffusion layer.

According to an embodiment of this disclosure, the plate has a through hole, a conducive layer disposed on an internal surface of the through hole, the conducive layer connected to the surface circuit and the heat diffusion layer respectively, a conductor fastener arranged in the through hole, and the conductor fastener connected to the heat dissipation device.

According to an embodiment of this disclosure, the heat dissipation device is electrically connected to the heat diffusion layer through the conductor fastener and the conducive layer.

According to an embodiment of this disclosure, the plate has a plurality of insulating layers and a plurality of circuit layers, and the insulating layers and the circuit layers are stacked alternately.

According to an embodiment of this disclosure, a thermal conductivity of the thermally conductive insulating layer is greater than a thermal conductivity of the insulating layer.

This disclosure is directed to a stack-up structure of a printed circuit board having a plate, a thermally conductive insulating layer, a heat diffusion layer and a thermal conductor. The plate has a first surface and a second surface opposite to each other, the plate has a plurality of insulating layers and a plurality of circuit layers. The thermally conductive insulating layer covers the second surface and is pressed to combine with the second surface, and a thermal conductivity of the thermally conductive insulating layer is greater than a thermal conductivity of the insulating layer. The heat diffusion layer covers the thermally conductive insulating layer and is pressed to combine with the thermally conductive insulating layer. The thermal conductor is embedded in the plate and connected with the first surface and the thermally conductive insulating layer, respectively.

This disclosure is directed to a solid state transformer having a plurality of power conversion module, at least one of the power conversion modules has a stack-up structure of a printed circuit board, the stack-up structure of the printed circuit board has a plate, a plurality of power devices, a thermally conductive insulating layer, a heat diffusion layer and a plurality of thermal conductors. The plate has a first surface and a second surface opposite to each other. The power devices are arranged on the first surface. The covers the second surface and is pressed to combine with the second surface. The heat diffusion layer covers the thermally conductive insulating layer and is pressed to combine with the thermally conductive insulating layer. The thermal conductors are embedded in the plate and respectively connected with the power device and the thermally conductive insulating layer.

According to an embodiment of this disclosure, the solid state transformer further has a heat dissipation device, the heat dissipation device assembled on the plate and the heat diffusion layer is disposed between the heat dissipation device and the thermally conductive insulating layer According to an embodiment of this disclosure, the heat dissipation device is electrically connected with the heat diffusion layer.

According to an embodiment of this disclosure, the heat dissipation device is electrically connected with the heat diffusion layer.

According to an embodiment of this disclosure, a surface circuit is arranged on the first surface, and the power devices are electrically connected to the surface circuit, respectively.

According to an embodiment of this disclosure, the stack-up structure of the printed circuit board further has a heat dissipation device, the heat dissipation device is assembled on the plate so that the heat diffusion layer is disposed between the heat dissipation device and the thermally conductive insulating layer, the is defined with a through hole, a conducive layer is coated on an internal surface of the through hole, the conducive layer is connected to the surface circuit and the heat diffusion layer respectively, the through hole provided with a conductor fastener, the conductor fastener is connected to the heat dissipation device.

According to an embodiment of this disclosure, the heat dissipation device is electrically connected to the heat diffusion layer through the conductor fastener and the conducive layer.

According to an embodiment of this disclosure, the plate has a plurality of insulating layers and a plurality of circuit layers, and the insulating layers and the circuit layers are stacked alternately.

According to an embodiment of this disclosure, a thermal conductivity of the thermally conductive insulating layer is greater than a thermal conductivity of the insulating layer.

According to an embodiment of this disclosure, the thermal conductors are copper blocks or ceramic blocks.

This disclosure is directed to a stack-up structure of a printed circuit board having a thermally conductive insulating layer therein. Therefore, during an assembling process, the times pf coating thermal paste applications are less than that of a related-art process. The step of assembling an insulation material is omitted so as to avoid mistake caused by manual operations which may lead to damage to a performance of the insulation material. The thermally conductive insulating layer may provide a characteristic of heat transfer so as to form a heat conducting path in a direction perpendicular to the plate and a uniform heat path along the plate. Therefore, the effect of heat dissipation of this disclosure may be improved.

### BRIEF DESCRIPTION OF THE DRAWINGS

The features of the disclosure believed to be novel are set forth with particularity in the appended claims. The disclosure itself, however, may be best understood by reference to the following detailed description of the disclosure, which describes a number of exemplary embodiments of the disclosure, taken in conjunction with the accompanying drawings, in which:

FIG. 1 is a cross-sectional view of a stack-up structure of a printed circuit board in exploded status according to an embodiment of this disclosure.

FIG. 2 is a cross-sectional view of the stack-up structure of the printed circuit board according to an embodiment of this disclosure.

FIG. 3 is a cross-sectional view of a stack-up structure of a printed circuit board according to another embodiment of this disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

Detailed descriptions and technical contents of this disclosure is described in the flowing paragraph with reference to the drawings. However, the drawings are attached only for illustration and are not intended to limit this disclosure.

It should be understood that the orientations or positional relationships in this disclosure which are indicated by the terms such as “front side”, “rear side”, “left side”, “right side”, “front end”, “rear end”, “end”, “vertical”, “horizontal”, “vertical”, “top” and “bottom” are based on the orientations or positional relationships as shown in the drawings. These are only used for describing this disclosure and simplifying the description rather than indicating or implying that the device or element have a specific orientation or be constructed and operated in a specific orientation, and it should not be considered as limitations of the scopes of this disclosure.

The terms used herein without additional definition such as “substantially” and “approximately” are used to describe and illustrate small changes. When used in an event or situation, the term may include the precise moment at which the event or situation occurs, and a close approximation to moment the event or situation occurs. For example, when combined with a numerical value, the term may include a range of variation less than or equal to ±10% of the numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

The detail descriptions and technical contents of this disclosure are described in the following paragraphs with reference to the drawings. However, the attached drawings are only used for illustrative purposes rather than limitations of the scopes of this disclosure.

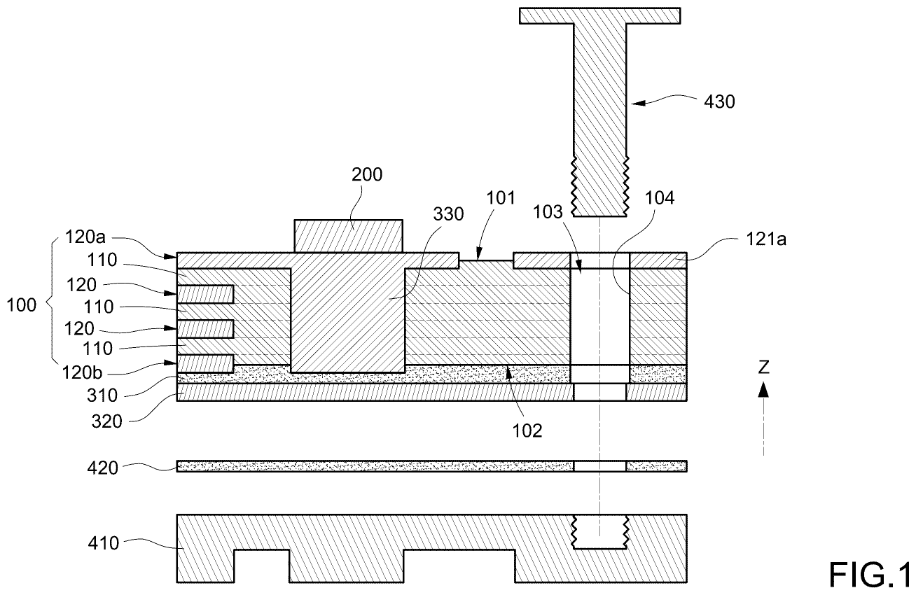

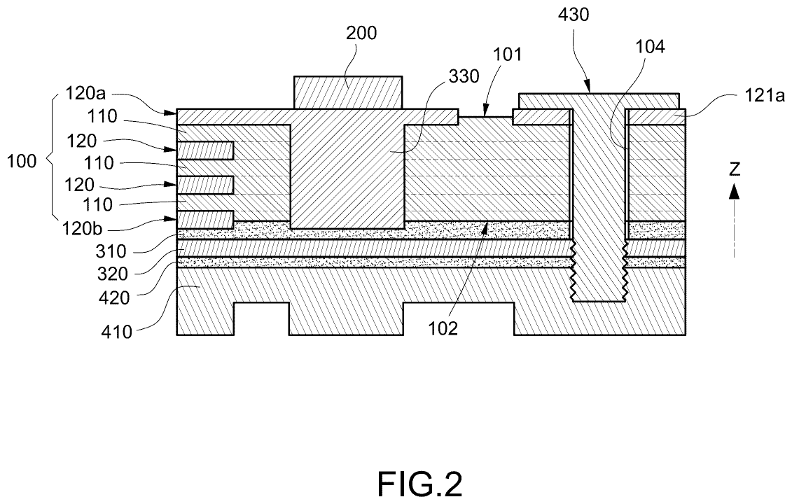

FIG. 1 is a cross-sectional view of a stack-up structure of a printed circuit board in exploded status according to an embodiment of this disclosure; FIG. 2 is a cross-sectional view of the stack-up structure of the printed circuit board according to an embodiment of this disclosure. A stack-up structure of a printed circuit board according to FIGS. 1 to 2 is provided in this disclosure, in a simplest embodiment, the stack-up structure of the printed circuit board has at least: a plate 100, a thermally conductive insulating layer 310, a heat diffusion layer 320 and a thermal conductor 330, and the stack-up structure of the printed circuit board may have a plurality of thermal conductor 330.

The plate 100 has a first surface 101 and a second surface 102 opposite to the first surface 101 which are disposed at two sides of the plate 100. The plate 100 has a layer-stack structure, specifically, the plate 100 has a plurality of insulating layers 110 and a plurality of circuit layers 120, and the insulating layers 110 and the circuit layers 120 are stacked alternately. Moreover, a surface circuit 120a is arranged on the first surface 101. The insulating layers 110 are made of FR4 glass fiber with a thermal conductivity within 0.2-0.8 W/mK.

The second surface 102 of the plate 100 is covered by the thermally conductive insulating layer 310, and the thermally conductive insulating layer 310 is combined to the second surface 102 by hot pressing. The thermally conductive insulating layer 310 performs good heat transfer and is used for insulation of the second surface 102. A thermal conductivity of the thermally conductive insulating layer 310 is greater than a thermal conductivity of the insulating layer 110, so as to improve a thermal conductivity of the plate 100. The thermal conductivity of the thermally conductive insulating layer 310 is greater than 0.8 W/mK, for example, the thermally conductive insulating layer 310 may be a piece made of FR4 glass fiber (for example, the thermal conductivity is within 0.8 W/mK to 2 W/mK), thermal conductive film or ceramic (the thermal conductivity is within 0.8 W/mK to 200 W/mK) or combination thereof, but scope of this disclosure should not be limited to the embodiments. The thermally conductive insulating layer 310 is made of materials with proper dielectric strength and proper thermal conductivity (K) which are selected according to operation requirements (e.g., operation voltage requirement, thickness limit of the circuit board, heat dissipation requirement). Accordingly, the insulation and the heat conductivity of the thermally conductive insulating layer 310 can meet requirements of insulation, operation voltage and heat conductivity, and the stack-up structure of the printed circuit board therefore has a whole thickness which is compact. Another surface circuit 120b is disposed on the second surface 102, the thermally conductive insulating layer 310 made of thermal conductive film is melted during hot pressing so as to eliminate steps between the second surface 102 and the surface circuit 120b thereon, so that gaps between the thermally conductive insulating layer 310 and the second surface 102 are therefore avoided.

The thermally conductive insulating layer 310 is covered by the heat diffusion layer 320, and the heat diffusion layer 320 may be combined to the thermally conductive insulating layer 310 by hot pressing. According to this embodiment, the heat diffusion layer 320 is a copper foil. An area of the thermally conductive insulating layer 310 is not larger than an area of the plate 100 of the stack-up structure of the printed circuit board. The thermally conductive insulating layer 310 is covered by the heat diffusion layer 320 as a copper paving, and an area of the heat diffusion layer 320 is not larger than the area of the thermally conductive insulating layer 310.

The plate 100 is provided with a through hole 103 as shown in FIG. 1 which may penetrate the plate 100 from the first surface 101 to the second surface 102, a conducive layer 104 is coated on an internal surface in the through hole 103, and the conducive layer 104 is respectively connected to the surface circuit 120a and the heat diffusion layer 320. According to this embodiment, the conducive layer 104 is a copper paving. The surface circuit 120a has a conductive contact 121a disposed at a periphery of the through hole 103 to connect to the conducive layer 104 in the through hole 103.

The thermal conductors 330 is embedded in the plate 100 and connected to the thermally conductive insulating layer 310. According to this embodiment, the thermal conductor 330 may be copper block(s) or ceramic block(s), the thermal conductor 330 may be formed by a method of configuring copper or ceramic at corresponding positions on the surface circuit 120a, the circuit layers 120 and the insulating layer 110 when manufacturing the circuit layers 120 and the surface circuit 120a, so as to form the thermal conductor 330 by accumulation.

The stack-up structure of the printed circuit board further has a power device 200, the power device 200 is not limited to a specific type in this disclosure. According this embodiment, for example, the power devices 200 may be a metal-oxide-semiconductor field-effect transistor (MOSFET) of a solid state transformer (STT) with high power density (for example, 40 W/L or more), the power device 200 can be made as a patch type structure to make the stack-up structure of the printed circuit board compact, but scopes of this disclosure should not be limited to the embodiment. According to this embodiment, the power device 200 is arranged on the first surface 101 of the plate 100 and electrically connected with the surface circuit 120a. The stack-up structure of the printed circuit board further has other electronic components, and the power device 200 mentioned above and other electronic components are disposed together on the first surface 101 of the plate 100 and electrically connected with the surface circuit 120a. According to this embodiment, the power device 200 is connected to the thermal conductor 330.

The stack-up structure of the printed circuit board further has a heat dissipation device 410 and a thermally conductive layer 420, the heat dissipation device 410 is assembled on the plate 100, and the heat diffusion layer 320 is disposed between the heat dissipation device 410 and the thermally conductive insulating layer 310, the heat dissipation device 410 may be a heat dissipation piece. The thermally conductive layer 420 is disposed between the heat dissipation device 410 and the heat diffusion layer 320, the thermally conductive layer 420 may be thermal paste. For example, the thermal paste is applied on a surface of the heat dissipation device 410 to form the thermally conductive layer 420, and the thermally conductive layer 420 is then attached to the heat diffusion layer 320. Specifically, the heat diffusion layer 320 is defined with an area according to a contact area between the heat diffusion layer 320 and the heat dissipation device 410. A conductor fastener 430 such as a metal bolt is arranged on the through hole 103. The conductor fastener 430 screws the heat dissipation device 410 so as to fasten the heat dissipation device 410 onto one sided of the plate 100 corresponding to the second surface 102. A head is disposed at one end of the metal bolt to abut against the conductive contact 121a of the surface circuit 120a. According to an applying region of the thermally conductive layer 420, the conductor fastener 430 may penetrates the thermally conductive layer 420 or bypass the thermally conductive layer 420 (namely disposed as an arrangement not shown in figures which is outside a periphery of the thermally conductive layer 420). Moreover, the heat dissipation device 410 is electrically connected to the heat diffusion layer 320 through the conductor fastener 430 and the conducive layer 104 in the through hole 103, so that the heat dissipation device 410 and the heat diffusion layer 320 are disposed at the same potential to avoid unexpected currents, and an insulation process between the plate 100 and the heat dissipation device 410 is not necessary. The heat dissipation device 410 and the plate 100 are insulated by the thermally conductive insulating layer 310, in a limited thickness of the stack-up structure of the printed circuit board, a potential difference between the power device 200 and the heat dissipation device 410 may be blocked by the thermally conductive insulating layer 310. The heat dissipation device 410 is thermally connected to the power device 200 sequentially through the thermally conductive layer 420, the heat diffusion layer 320, the thermally conductive insulating layer 310 and the thermal conductor 330. Accordingly, heat generated by the power device 200 in an operation can be transferred to the heat dissipation device 410 through the path mentioned above and further dissipated to the environment.

In an assembly process of the stack-up structure of the printed circuit board of this disclosure, the thermally conductive insulating layer 310 and the heat diffusion layer 320 are pre-pressed to combine with the plate 100, so that only one time of disposing the thermally conductive layer 420 (for example, applying the thermal paste) is required. Therefore, during an assembling process, the times of applying thermal paste are less than that of a related-art process and thus the assembling efficiency is increased. The step of assembling an insulation material is omitted so as to avoid mistake caused by manual operations which may lead to damage to a performance of the insulation material. The thermally conductive insulating layer 310 may provide a characteristic of heat transfer so as to form a heat conducting path in a direction Z normal to the plate 100 (namely a direction perpendicular to the plate 100) and a uniform heat path along the plate 100. Therefore, the effect of heat dissipation of this disclosure may be improved.

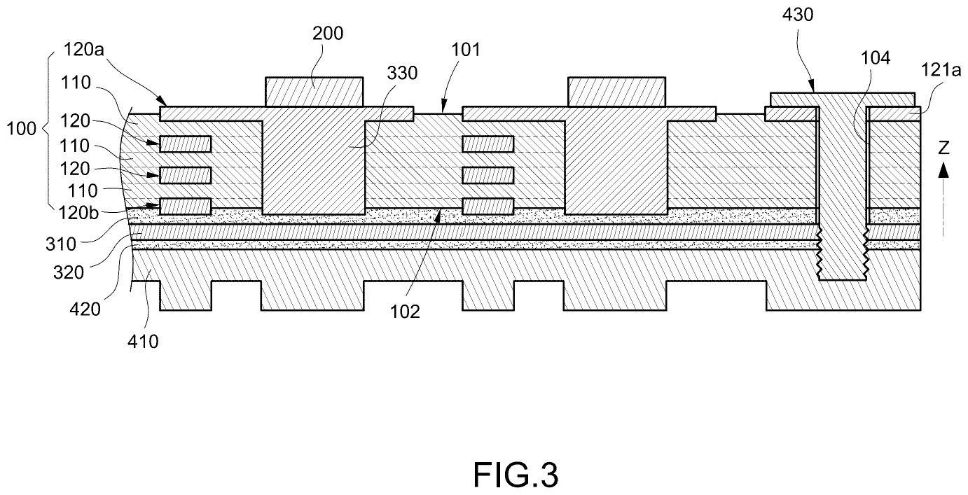

FIG. 3 is a cross-sectional view of a stack-up structure of a printed circuit board according to another embodiment of this disclosure. According to, the stack-up structure of the printed circuit board of this disclosure as shown in FIG. 3, a plurality of power devices 200 may be arranged on the first surface 101 of the plate 100, and a plurality of thermal conductors 330 corresponding to the power devices 200 are embedded in the plate 100. The thermal conductors 330 are connected to the same thermally conductive insulating layer 310 and the power devices 200, respectively. The thermally conductive insulating layer 310 can be used for blocking potential differences between the power devices 200 and blocking potential differences between the heat dissipation device 410 and the power devices 200 respectively. The embodiments of this disclosure are suitable for a solid state transformer (SST) having multiple power conversion module, the at least one power conversion module has the stack-up structure of the printed circuit board of the embodiment of this disclosure, so as to meet an operation voltage requirement and a heat dissipation requirement of a medium and high voltage system.

Although this disclosure has been described with reference to the foregoing embodiment, it will be understood that the disclosure is not limited to the details thereof. Various equivalent variations and modifications can still occur to those skilled in this art in view of the teachings of this disclosure. Thus, all such variations and equivalent modifications are also embraced within the scope of this disclosure as defined in the appended claims.

What is claimed is:

1. A stack-up structure of a printed circuit board, the stack-up structure comprising:
a plate, comprising a first surface and a second surface opposite to each other;
a power device, arranged on the first surface;
a thermally conductive insulating layer, covering the second surface and combined with the second surface in a pressed manner;
a heat diffusion layer, covering the thermally conductive insulating layer and combined with the thermally conductive insulating layer in the pressed manner; and
a thermal conductor, embedded in the plate and connected with the power device and the thermally conductive insulating layer, respectively.

2. The stack-up structure according to claim 1, further comprising a heat dissipation device, assembled on the plate, and the heat diffusion layer disposed between the heat dissipation device and the thermally conductive insulating layer.

3. The stack-up structure according to claim 2, wherein the heat dissipation device is electrically connected with the heat diffusion layer.

4. The stack-up structure according to claim 2, further comprising a thermally conductive layer, disposed between the heat dissipation device and the heat diffusion layer.

5. The stack-up structure according to claim 4, wherein the heat dissipation device is thermally connected to the power device through the thermally conductive layer, the heat diffusion layer, the thermally conductive insulating layer and the thermal conductor.

6. The stack-up structure according to claim 1, wherein a surface circuit is arranged on the first surface, the power device is electrically connected to the surface circuit.

7. The stack-up structure according to claim 6, further comprising a heat dissipation device, assembled on the plate, the heat diffusion layer disposed between the heat dissipation device and the thermally conductive insulating layer, the plate comprising a through hole, a conducive layer disposed on an internal surface of the through hole, the conducive layer connected to the surface circuit and the heat diffusion layer respectively, a conductor fastener arranged in the through hole, and the conductor fastener connected to the heat dissipation device.

8. The stack-up structure according to claim 7, wherein the heat dissipation device is electrically connected to the heat diffusion layer through the conductor fastener and the conducive layer.

9. The stack-up structure according to claim 1, wherein the plate comprises a plurality of insulating layers and a plurality of circuit layers, and the insulating layers and the circuit layers are stacked alternately.

10. The stack-up structure according to claim 9, wherein a thermal conductivity of the thermally conductive insulating layer is greater than a thermal conductivity of the insulating layer.

11. A stack-up structure of a printed circuit board, the stack-up structure comprising:
a plate, comprising a first surface and a second surface opposite to each other, and comprising a plurality of insulating layers and a plurality of circuit layers;
a thermally conductive insulating layer, covering the second surface and combined with the second surface in a pressed manner, wherein a thermal conductivity of the thermally conductive insulating layer is greater than a thermal conductivity of each insulating layer;
a heat diffusion layer, covering the thermally conductive insulating layer and combined with the thermally conductive insulating layer in the pressed manner; and
a thermal conductor, embedded in the plate and connected with the first surface and the thermally conductive insulating layer, respectively.

12. A solid state transformer, comprising a plurality of power conversion modules, at least one of the power conversion modules comprising a stack-up structure of a printed circuit board, the stack-up structure comprising:
a plate, comprising a first surface and a second surface opposite to each other;
a plurality of power devices, arranged on the first surface,
a thermally conductive insulating layer, covering the second surface and combined with the second surface in a pressed manner;
a heat diffusion layer, covering the thermally conductive insulating layer and combined with the thermally conductive insulating layer in a pressed manner; and
a plurality of thermal conductors, embedded in the plate and respectively connected with the power devices and the thermally conductive insulating layer.

13. The solid state transformer according to claim 12, wherein the stack-up structure further comprises a heat dissipation device assembled on the plate, the heat diffusion layer is disposed between the heat dissipation device and the thermally conductive insulating layer, and the heat dissipation device is electrically connected with the heat diffusion layer.

14. The solid state transformer according to claim 13, wherein the stack-up structure further comprises a thermally conductive layer, the thermally conductive layer is disposed between the heat dissipation device and the heat diffusion layer, and the heat dissipation device is connected to the power devices through the thermally conductive layer, the heat diffusion layer and the thermally conductive insulating layer, and the thermal conductors.

15. The solid state transformer according to claim 12, wherein a surface circuit is arranged on the first surface, and the power devices are electrically connected to the surface circuit, respectively.

16. The solid state transformer according to claim 15, wherein the stack-up structure further comprises a heat dissipation device assembled on the plate, the heat diffusion layer is disposed between the heat dissipation device and the thermally conductive insulating layer, a through hole is defined on the plate, a conducive layer is disposed on an internal surface of the through hole, the conducive layer is connected to the surface circuit and the heat diffusion layer respectively, a conductor fastener is disposed in the through hole, and the conductor fastener is connected to the heat dissipation device.

17. The solid state transformer according to claim 16, wherein the heat dissipation device is electrically connected to the heat diffusion layer through the conductor fastener and the conducive layer.

18. The solid state transformer according to claim 12, wherein the plate comprises a plurality of insulating layers and a plurality of circuit layers, and the insulating layers and the circuit layers are stacked alternately.

19. The solid state transformer according to claim 12, wherein a thermal conductivity of the thermally conductive insulating layer is greater than a thermal conductivity of each insulating layer.

20. The solid state transformer according to claim 12, wherein the thermal conductors are copper blocks or ceramic blocks.
